(19) United States
(12) Patent Application Publication
(10) Pub. No.: US 2010/0006976 A1
(43) Pub. Date: Jan. 14, 2010

(54) SEMICONDUCTOR DEVICE AND MANUFACTURING METHOD THEREOF

(76) Inventors: Ippei Kume, Tokyo (JP); Naoya Inoue, Tokyo (JP); Yoshihiro Hayashi, Tokyo (JP)

Correspondence Address: Mr. Jackson Chen, 6535 N. STATE HWY 161, IRVING, TX, 75039, US

(21) Appl. No.: 12/530,729

(22) PCT Filed: Feb. 27, 2008
(86) PCT No.: PCT/JP2008/053883

§ 371 Date: Sep. 10, 2009

(30) Foreign Application Priority Data
Mar. 19, 2007 (JP) 2007-071273

(51) Int. Cl. H01L 29/76; H01L 21/20

(52) U.S. Cl. 257/516; 438/381; 257/E21.09; 257/E29.226

(57) ABSTRACT

This invention provides a semiconductor device having a capacitor with reduced deterioration of dielectric constant and reduced leakage between upper and lower electrodes and a manufacturing method of such a semiconductor device. A capacity structure is configured by sequentially stacking a lower electrode, a capacitive insulation film, and an upper electrode on wiring or a contact plug. The capacity structure is of a thin-film capacitor structure having, at the interface between the lower electrode and the capacitive insulation film, a thin metal film having insulating properties and exhibiting a high dielectric constant.

### TECHNICAL FIELD

This invention relates to a semiconductor device having a thin-film capacitor structure provided on a multilayer wiring structure or in a multilayer wiring, and a manufacturing method of such a semiconductor device.

### BACKGROUND ART

Conventional capacitors for high-frequency devices or decoupling capacitors employ a PIP (polysilicon/insulation film/polysilicon) structure in which polysilicon is used for both upper and lower electrodes, while ONO (silicon oxide film-silicon nitride film-silicon oxide film) is used as a capacitive insulation film, or an MOS (polysilicon electrode/gate silicon oxide film/silicon substrate) capacitor. However, electrodes using polysilicon have problems such as high resistance and occurrence of depletion. In order to overcome these problems, the trend is to employ, for electrodes, a MIM (metal/capacitive insulation film/metal) structure in which a metal and a metal oxide film such as a titanium nitride or ruthenium tetroxide film are used.

On the other hand, in order to meet demands for thin-film capacitors having increased capacity and reduced area, studies have been made on the possibility of using an MIM structure in which a high dielectric material (high-k material) is used for an insulation film, in place of the conventional ONO structure or insulation film structure using a gate oxide film. Typical high-k materials comprise tantalum oxide and niobium oxide. In recent trend, even when a high-k insulation film is used for realizing an MIM structure with a capacity density as high as 10 fF/mm² or more, the film thickness is in some cases required to be reduced to 20 nm or less.

Formation of such metal oxide films is performed under oxygen atmosphere. The film formation is typically performed by an ALD (Atomic Layer Deposition) method, sputtering method, or chemical deposition method, and these methods require high temperature oxygen atmosphere during the film formation. When the substrate temperature is increased under oxygen atmosphere for film formation of a high-k material, the surface of a metal film of the lower electrode is also oxidized. If the thickness reduction of dielectric films is pursued to an extent that a dielectric film with a thickness in a range of 20 nm or less is used for the purpose of increasing the capacity, a several-nm thick metal film having the oxidized surface will occupy several tens of percent in the dielectric insulation film. Titanium nitride films have been widely considered for electrodes in MIM structures. This is because titanium nitride films have low electric resistance and are easy to etch. However, the titanium nitride films also have a natural oxide film on the surface thereof and oxidation occurs during formation of a metal oxide film.

When the capacity per unit area is increased by reducing the thickness of the capacitive insulation film, as described above, the effect of the oxide film on the surface of the lower electrode becomes relatively great. For the purpose of preventing such oxidation reaction, numerous studies have been performed for developing barrier films.

First Prior Art Example:

Japanese Laid-Open Patent Publication No. 2004-266010 (Patent Document 1) discloses a method in which a SiO₂ film is used as a barrier film for preventing diffusion of oxygen in a high-k material, and a SiN film is used as a barrier film for preventing oxidation of electrodes. The diffusion of oxygen from the high-k material can be prevented by forming SiN/SiO₂ films and SiO₂/SiN films at the interface with the upper electrode and the interface with the lower electrode, respectively. The use of barrier films enables uniform formation of a capacitive insulation film from the inside of the film to the interfaces with the electrodes without deterioration of characteristics.

Second Prior Art Example:

Japanese Laid-Open Patent Publication No. 2001-168301 (Patent Document 2) discloses a method of utilizing a titanium oxide film formed on the surface of a titanium nitride film during formation thereof. A titanium oxide layer with a thickness of 0.2 to 1 nm is formed on the surface of an electrode while changing the conditions for forming a high-k material film. The thin formation of the film makes it possible to minimize the effect of the instable dielectric constant of the titanium oxide film as shown in FIG. 2. Additionally, the formation of the thin titanium oxide film on the surface of the electrode makes it possible to reduce the leakage current.

Third Prior Art Example:

Japanese Laid-Open Patent Publication No. 2003-174092 (Patent Document 3) proposes a stacked electrode structure in which a capacitive insulation film is sandwiched between TaN electrodes to prevent oxidation of the electrodes, and this TaN/TaO/TaN structure is sandwiched between Ta films to form a Ta/TaN/TaO/TaN/Ta structure. The use of TaN having oxidative resistance for electrodes makes it possible to prevent oxidation of the surfaces of the electrodes during formation of the TaO films, and to prevent the capacity reduction. Further, the stacked structure of TaN/Ta makes it possible to reduce the electric resistance of the electrodes.

### DISCLOSURE OF THE INVENTION

However, the first to third prior art examples have problems as described below.

In the first prior art example, a SiO2 film and a SiN film are formed as barrier films so as to sandwich a capacity film. Although the SiO₂ and SiN films are very effective as barrier films, both of them have a relative dielectric constant corresponding to a half or less of that of the high-k material. Therefore, the use of these barrier films causes significant reduction of the capacity.

The second prior art example utilizes oxidation of the surface of the lower electrode during film formation. In contrast with the first prior art example, the use of a thin surface oxide film as a barrier film makes it possible prevent the reduction of the capacity. However, the surface oxide film does not serve as a barrier for preventing diffusion of oxygen from the high-k material, whereas the diffusion of oxygen is prevented in the first prior art example. Oxygen is diffused toward the electrode from the interface of the high-k material by oxidation reaction at the surface of the metal film, and the leakage current is rate-limited at the electrode interface. According to the second prior art example, the problem of oxygen diffusion cannot be solved since the surface of the lower electrode is oxidized.

The third prior art example tries to prevent diffusion of oxygen from TaO by using a TaN film having oxidative resistance for an electrode. FIG. 4 shows results of an experiment to form a TaO film on TaN by sputtering. Calculating a film formation rate based on FIG. 4, an initial oxide film with a thickness of 4 nm is present. Since the initial oxide film is formed of TaO, a high-k material, the significant reduction of dielectric constant will not occur, but the diffusion of oxygen cannot be prevented. If oxygen is diffused at the electrode interface in the TaO MIM, the barrier height at the interface will be reduced and the leakage current will be increased.

This invention has been proposed to solve the problems described above, and provides a semiconductor device comprising a capacitor with high capacity and yet with low interelectrode leakage current, and a manufacturing method of such a semiconductor device.

This invention provides a semiconductor device characterizing by comprising a thin-film capacitor structure formed on wiring or a contact plug, the capacitor being of a structure configured by stacking a lower electrode, a thin metal film, a capacitive insulation film, and an upper electrode sequentially in this order, and having a high dielectric insulation film formed by plasma oxidation on the surface of the thin metal film sandwiched between the lower electrode and the capacitive insulation film. These process steps are shown in FIG. 3.

### ADVANTAGEOUS EFFECTS OF THE INVENTION

A thin-film capacitor structure according to the present invention realizes a semiconductor device comprising a capacitor with reduced deterioration of dielectric constant and reduced leakage between upper and lower electrodes, and a manufacturing method of such a semiconductor device.

When a metal oxide, a high-k material, is used for a capacitive insulation film, a thin metal film is first stacked on a lower electrode. A tantalum nitride film or nitrogen-containing tantalum film is used as the thin metal film. A tantalum nitride film may be stacked on a tantalum film. Any other metal film or metal nitride film may be used as long as it is easy to plasma oxidize. The thin metal film described above is stacked on the lower electrode, and then only the surface of the tantalum nitride film or nitrogen-containing tantalum film in the uppermost layer of the thin metal film is oxidized by plasma oxidation to form a tantalum oxy-nitride film. This oxidation process of the tantalum nitride film or nitrogen-containing tantalum film may be performed on either the entire or only the surface of the film. The formation of a sufficiently saturated oxide layer on the surface of the lower electrode makes it possible to realize a dielectric film which is homogenous from the interface with the electrode to the inside of the film. The formation of the oxide layer directly on the surface of the lower electrode makes it possible to prevent unintended oxidation of the lower electrode during the formation of the capacitive insulation film, and to prevent diffusion of oxygen from the capacitive insulation film. The tantalum oxy-nitride film has a higher dielectric constant (k˜25) compared to the oxygen barrier film according to the prior art examples, and hence it is possible to prevent reduction of the capacity value caused by a low-dielectric barrier film.

This invention makes it possible to manufacture a semiconductor device having a thin-film capacitor with reduced leakage between upper and lower electrodes.

### BRIEF DESCRIPTION OF THE DRAWINGS

FIG. 1 is a cross-sectional view showing a basic structure of an MIM capacitor according to an embodiment of this invention;

FIG. 2 is a diagram showing a relationship between thermal processing temperature (abscissa) and dielectric constant (ordinate) for a titanium oxide film;

FIG. 3 is a diagram showing a flow of processing an MIM capacitor according to an embodiment of this invention;

FIG. 4 is a diagram showing thickness of an oxide layer formed during sputtering of a tantalum film;

FIG. 5 is a diagram showing selectivity of plasma oxidation for a tantalum film and a tantalum nitride film;

FIG. 6 is diagrams showing a manufacturing method of a thin-film capacitor described in a first embodiment example of this invention;

FIG. 7 is diagrams showing a manufacturing method of a thin-film capacitor described in a second embodiment example of this invention;

FIG. 8 is diagrams showing a manufacturing method of a thin-film capacitor described in a third embodiment example of this invention;

FIG. 9 is diagrams showing a manufacturing method of a thin-film capacitor described in a fourth embodiment example of this invention;

FIG. 10 is a diagram showing a wiring structure incorporating a thin-film capacitor described in a fifth embodiment example of this invention;

FIG. 11 is a diagram showing a wiring structure incorporating a thin-film capacitor described in a sixth embodiment example of this invention; and

FIG. 12 is a diagram showing a wiring structure incorporating a thin-film capacitor described in a seventh embodiment example of this invention.

### BEST MODE FOR CARRYING OUT THE INVENTION

Best modes for carrying out this invention will be described based on the accompanying drawings.

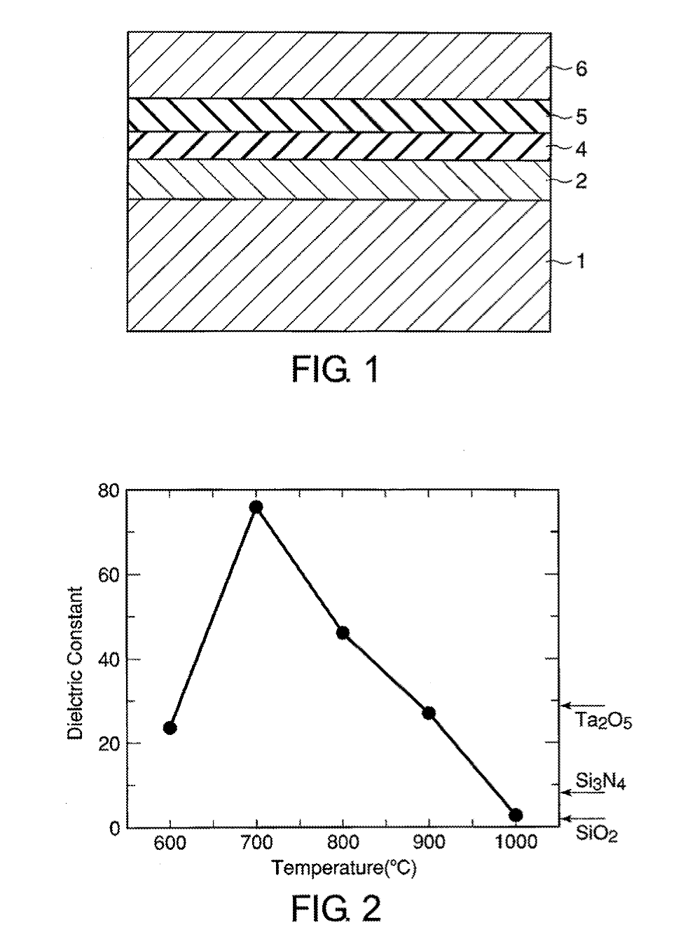

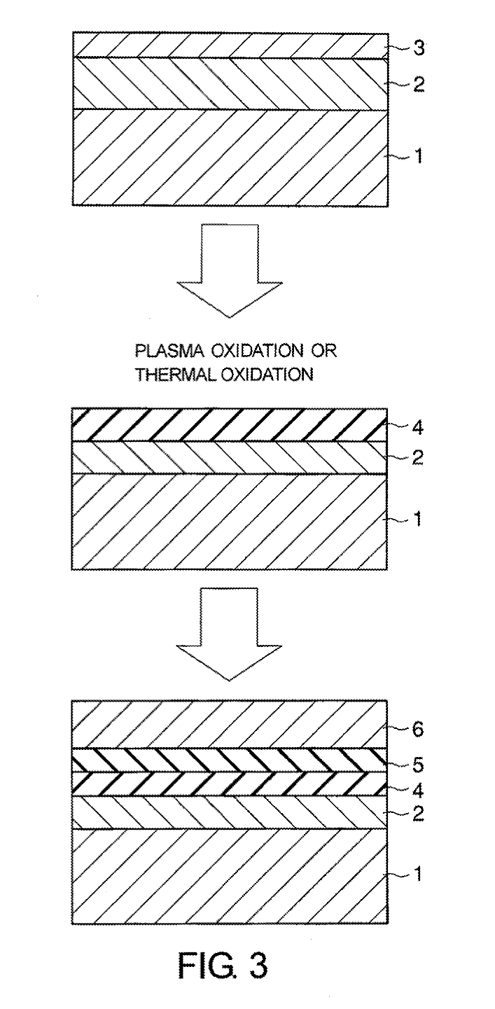

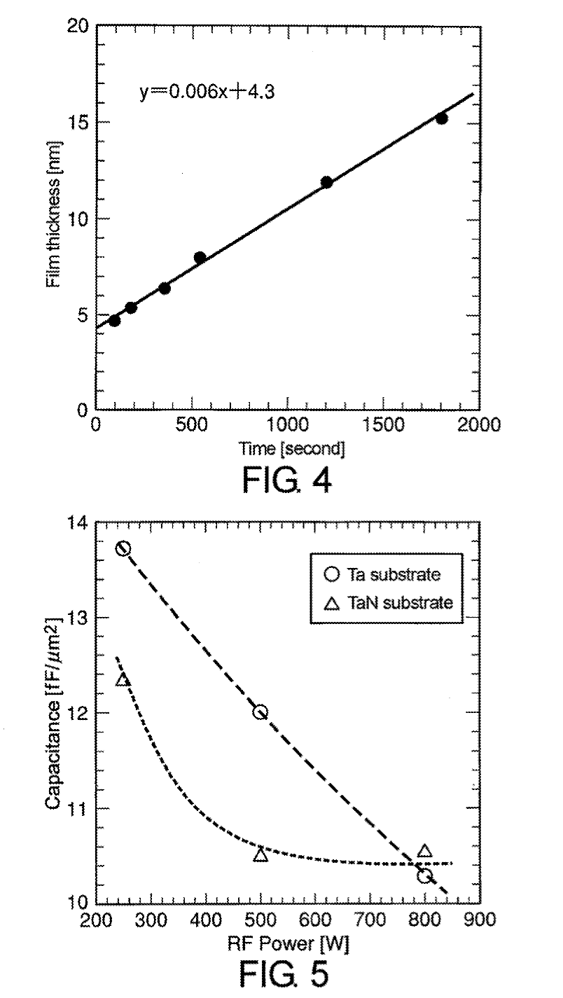

FIG. 1 is a cross-sectional view showing a part of a capacity element for embodying the present invention. A titanium nitride film is used as a lower electrode film 1, while a tantalum film 2 and a tantalum nitride film 3 are used as thin metal films stacked on the lower electrode. A tantalum oxy-nitride film 4 is formed by plasma oxidation of the tantalum nitride film. If the capacity film thickness is not enough, a tantalum oxide film is formed as a capacitive insulation film 5, and then a titanium nitride film is stacked thereon as an upper electrode film 6.

When comparing the results of plasma oxidation between a tantalum film and a tantalum nitride film, as shown in FIG. 5, the tantalum nitride film is easier to plasma oxidize. As seen from FIG. 5, for the tantalum nitride film, oxidation has already been saturated at a power of 500 W, and oxidation selectivity is very large. In the case of thermal oxidation, the tantalum film is oxidized more easily than the tantalum nitride film, but the selectivity of thermal oxidation is smaller than that of plasma oxidation. The stacked structure of the tantalum nitride film and the tantalum film makes it possible to utilize the difference in selectivity of plasma oxidation to saturate oxidation only of the tantalum nitride film while keeping the conductivity of the tantalum film. As a result, a barrier height is established at the interface between the tantalum film and a tantalum oxy-nitride film obtained by oxidizing the entire of the tantalum nitride film, and a low-leakage MIM can be obtained. An alternative effective approach is a method of oxidizing only the surface of the tantalum nitride film until sufficient saturation is gained in a short period of time under extremely strong oxidation conditions. According to this method, a desirable interface can be formed without the need of considering the oxidation selectivity of the layered film structure, and an even higher energy barrier can be established at the interface between the tantalum oxy-nitride film and the tantalum nitride film thus formed, whereby the leakage current can be reduced further more. It is desirable that plasma conditions for performing this method be set such that oxygen or nitrogen monoxide is used as the primary gas and the gas is supplied at a low pressure and high flow rate in order to stimulate dissociation in plasma.

### EMBODIMENT EXAMPLES

Specific embodiment examples of this invention will be described in detail with reference to the drawings.

### First Embodiment Example

### MIM Structure 1 Incorporated in ULSI Wiring

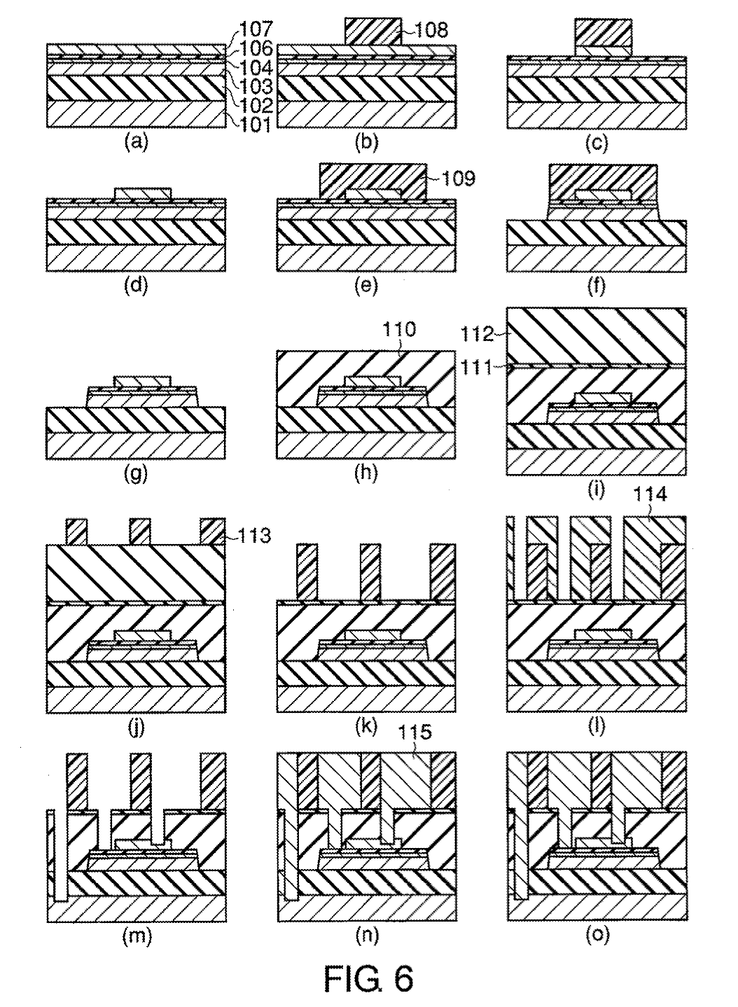

As shown in FIG. 6, a first embodiment example relates to an MIM structure incorporated in an actual ULSI wiring structure.

First, a 200-nm thick silicon oxide film 102 is formed on lower wiring 101 by plasma CVD. A 140-nm thick polycrystalline titanium nitride film 103 is formed as a lower electrode, a 5- to 10-nm thick tantalum film 104 is formed as a thin metal film, and a 5-nm thick tantalum nitride film 105 is formed. After that, the tantalum nitride film is plasma oxidized to produce a tantalum oxy-nitride film 106. The single layer of the tantalum film 104 may be oxidized by nitrogen monoxide (N₂O) plasma to form a tantalum oxy-nitride film. A 100-nm thick titanium nitride film 107 is formed as an upper electrode film (FIG. 6(a)). The titanium nitride film 103, the tantalum film 104, the tantalum nitride film 105, and the titanium nitride film 107 can be formed by sputtering or CVD deposition method.

Subsequently as shown in FIG. 6(b), a photoresist 108 is patterned such that an upper electrode of a desired size can be obtained. Further, as shown in FIG. 6(c), the titanium nitride film 107 is etched using the photoresist 108. The photoresist 108 is peeled off after the etching as shown in FIG. 6(d). Subsequently, as shown in FIG. 6(e), a photoresist 109 is patterned so as to form a lower electrode of a desired size. The photoresist 109 is patterned such that the upper electrode 6 is totally covered with the photoresist 109. As shown in FIG. 6(f), the tantalum oxide film 106, the tantalum film 104, and the titanium nitride film 103 are etched using the photoresist 109.

Subsequently, as shown in FIG. 6(g), the photoresist 109 is peeled off after the etching. Then, a 1400-nm thick silicon oxide film 110 to be a via interlayer film is formed by plasma CVD to cover all over the MIM structure, and CMP is performed to eliminate the difference in surface level (FIG. 6(h)). After forming a 120-nm thick silicon carbon nitride film 111 is formed as a trench stopper by plasma CVD, a 1200-nm thick silicon oxide film 112 is formed as a trench interlayer film by plasma CVD (FIG. 6(i)). Subsequently, as shown in FIG. 6(j), a photoresist 113 is applied and patterned in a width corresponding to a desired width of upper wiring. The silicon oxide film 112 is etched by plasma using fluoro-carbon gas, and the photoresist 113 is peeled off (FIG. 6(k)). A photoresist 114 is applied so as to cover the upper wiring patterns, and the photoresist 114 is patterned with desired upper vias (FIG. 6(l)). After the silicon carbon nitride film 111 and the silicon oxide film 110 are etched by plasma using fluorocarbon gas, the photoresist 114 is peeled off (FIG. 6(m)).

After that, a barrier film and a copper film 115 are buried in the trenches and vias and the structure is polished by CMP, whereby contacts to connect between upper and lower wiring lines are formed and, at the same time, an MIM structure is obtained in which a contact can be established at the upper wiring (FIG. 6(n)). In the embodiment example described above, as shown in FIG. 6(o), it is also possible to manufacture the MIM structure by etching the tantalum oxy-nitride film 106 simultaneously with the etching of the titanium nitride film 107.

### Second Embodiment Example

### MIM Structure 2 Incorporated in ULSI Wiring

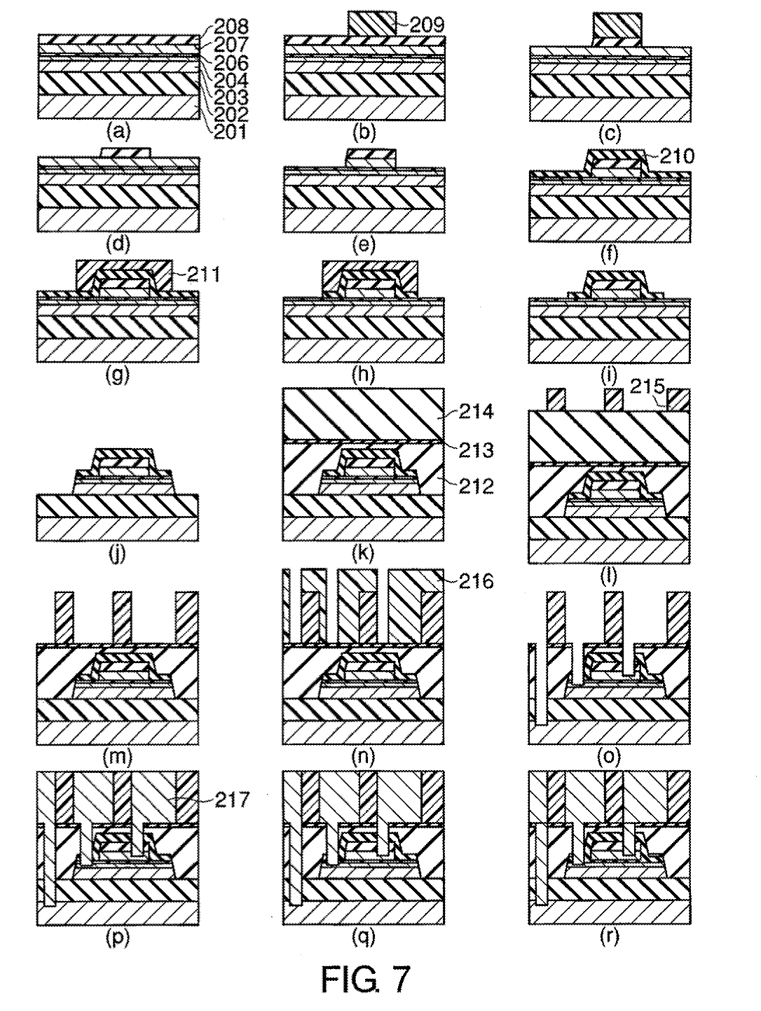

The MIM structure according to this invention may be manufactured by a method using a hard mask film. This method will be described with reference to FIG. 7.

First, in the same manner as shown in FIG. 6(a), a 200-nm thick silicon oxide film 202 is formed on lower wiring 201 by plasma CVD. A 140-nm thick titanium nitride film 203 is formed as a polycrystalline film, and a 10-nm thick tantalum film 204 and a 5-nm thick tantalum nitride film 205 are formed as thin metal films. The tantalum nitride film 205 is then plasma oxidized to form a tantalum oxy-nitride film 206. A 100-nm thick titanium nitride film 207 is formed as an upper electrode film. Further, a 100-nm thick silicon nitride film 208 is formed as a hard mask film by plasma CVD (FIG. 7(a)). The combination of materials for the hard mask film 208 and the upper electrode film 207 may be selected such that the upper electrode film 207 is resistant to etching when the hard mask film 208 is etched, while, conversely, the hard mask film 208 is resistant to etching when the upper electrode film 207 is etched.

Subsequently as shown in FIG. 7(b), a photoresist 209 is patterned so as to obtain an upper electrode of a desired size. Then, as shown in FIG. 7(c), the silicon nitride film 208 is etched using the photoresist 209. Subsequently, the photoresist 209 is peeled off after the etching as shown in FIG. 7(d). Then, as shown in FIG. 7(e), the titanium nitride film 207 is etched using the silicon nitride film 208 as a mask. The use of the hard mask film for processing steps prevents occurrence of an unusual shape called “fence” even if not only the tantalum oxy-nitride film 206 but also the tantalum film 205 is also etched during the etching of the titanium nitride film 207, whereby an etching product is caused to adhere to the side walls. The silicon nitride film 208 as the hard mask film can also serve as a stopper during via etching in a post-process.

Subsequently, as shown in FIG. 7(f), a silicon nitride film 210 is formed as a hard mask film all over the surface. The combination of materials for the hard mask film 210 and the lower electrode films 203 and 204 may be selected such that the lower electrode films 203 and 204 are resistant to etching when the hard mask film 210 is etched, while, conversely, the hard mask film 210 is resistant to etching when the lower electrode films 203 and 204 are etched. Then, as shown in FIG. 7(g), a photoresist 211 is patterned so as to obtain a lower electrode of a desired shape. The photoresist 211 is patterned to cover the entire of the upper electrode structure. As shown in FIG. 7(h), the silicon nitride film 210 is etched using the photoresist 211.

Subsequently, as shown in FIG. 7(i), the photoresist 211 is peeled off after the etching. Then, as shown in FIG. 70), the tantalum oxide film 206, the tantalum film 204, and the titanium nitride film 203 are sequentially etched using the silicon nitride film 210 as a mask. The use of the hard mask film for processing steps prevents occurrence of an unusual shape called “fence” even if an etching product adheres to the side wall during the etching of the tantalum film 204. The silicon nitride film 210 as the hard mask film can serve also as a stopper during via etching in a post-process. A 1400-nm thick silicon oxide film 212 to be a via interlayer film is formed by plasma CVD to cover the entire of the MIM structure, and CMP is performed to eliminate the difference in surface level. Further, a 120-nm thick silicon carbon nitride film 213 is formed as a trench stopper by plasma CVD, and then a 1200-nm thick silicon oxide film 214 is formed as a trench interlayer film by plasma CVD (FIG. 7(k)).

Subsequently, as shown in FIG. 7(l), a photoresist 215 is applied and patterned in a width corresponding to a desired width of upper wiring. The silicon oxide film 214 is etched by plasma using fluorocarbon gas, and the photoresist 215 is peeled off (FIG. 7(m)). A photoresist 216 is applied so as to cover the upper wiring pattern, and the photoresist 216 is patterned with desired upper vias (FIG. 7(n)). After the silicon carbon nitride film 213 and the silicon oxide film 212 are etched by plasma using fluorocarbon gas, the photoresist 216 is peeled off (FIG. 7(o)).

After that, a barrier film and a copper film 217 are buried in the trenches and vias and the structure is polished by CMP, whereby contacts to connect between upper and lower wiring lines are formed and, at the same time, an MIM structure is obtained in which a contact can be established at the upper wiring (FIG. 7(p)).

In the embodiment example described above, as shown in FIG. 7(q), it is also possible to manufacture the MIM structure by etching the tantalum oxide film 206 simultaneously with the etching of the upper electrode film 207. As shown in FIG. 7(r), it is also possible to manufacture the MIM structure by etching the tantalum oxide film 206 simultaneously with the etching of the hard mask film 210. The single layer of the tantalum film 104 may be oxidized by nitrogen monoxide (N₂O) plasma to form a tantalum oxy-nitride film.

### Third Embodiment Example

### Lower Electrode Lining Structure

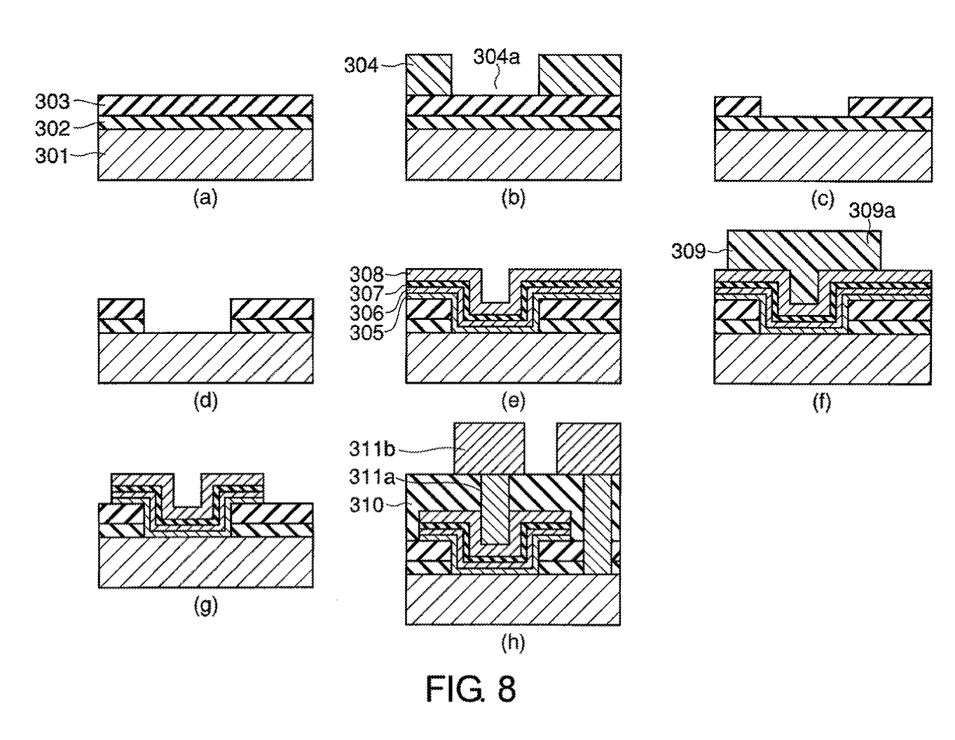

This third embodiment example relates to a semiconductor device in which a capacity element mounted on wiring has an upper electrode, a capacitive insulation film, and a lower electrode stacked in this order from the top. The semiconductor device is characterized in that the lower electrode in the capacity element is in direct contact with the top of the wiring located under the capacity element. FIG. 8 shows cross-sectional views of respective steps for implementing the embodiment of this invention. First, as shown in FIG. 8(a), a buried Cu wiring 301 is formed. A silicon nitride film or silicon carbon nitride film is formed to a thickness of 100 nm as a wiring cap insulation film 302 for preventing oxidation of Cu and diffusion of Cu, and a SiO₂ or SiOCH film is formed to a thickness of 150 nm as a hard mask 303. Then, a photoresist 304 is applied and a lower electrode contact formation pattern 304a is formed by photolithography. (FIG. 8(b))

Subsequently, the silicon oxide film 303 is etched by fluorocarbon plasma or the like using as a mask, the photoresist having the lower electrode contact formation pattern 304a formed therein. It is important, during the etching, to stop the etching on the wiring cap film 302 by utilizing the selectivity of dry etching. After forming a lower electrode contact pattern in the hard mask, the photoresist is removed by ashing to obtain a shape as shown in FIG. 8(c). The surface of the underneath Cu layer is not exposed during the ashing, which makes it possible to prevent the oxidation of the Cu by oxygen plasma. Then, the wiring cap film 302 is etched using the hard mask 303 having an opening pattern as a mask, whereby an opening pattern reaching the surface of the underneath Cu layer is formed as shown in FIG. 8(d).

Subsequently, as shown in FIG. 8(e), a 30-nm thick titanium nitride film 305 and a 5- to 10-nm thick tantalum film 306 are formed by a sputtering method to provide a lower electrode. The lower electrode may be formed by a single layer of the tantalum film 306 having a thickness of 10 to 30 nm k. A 5-nm thick tantalum oxy-nitride film 307 obtained by plasma oxidizing the tantalum nitride film is formed on the lower electrode. After that, a titanium nitride film 308 to be an upper electrode is formed thereon. A photoresist 309 is applied on the titanium nitride film 308, and an upper electrode pattern 309a is formed by photolithography so as to contain a lower electrode contact region therein (FIG. 8(f)). Using the upper electrode pattern 309a as a mask, the titanium nitride film 308, the tantalum oxy-nitride film 307, the tantalum film 306, and the titanium nitride film 305 are dry etched in this order (FIG. 8(g)). It is preferred to use chlorine/BCl₃ gas for the etching of the titanium nitride films 305 and 308, and to use fluorocarbon gas plasma for the etching of the tantalum oxy-nitride film 307 and the tantalum film 306. It is also preferred to set the substrate temperature to 50 degrees or higher in order to prevent adhesion of the deposit to the side walls during the etching of the tantalum-based films 307 and 306. After the dry etching, the resist 309 is peeled off. An insulation film 310 is deposited, and then an upper via 311a and upper wiring 311b are formed to establish contact with the thin-film capacitor (FIG. 8(h)).

According to this third embodiment example, the tantalum nitride film 6 on the lower electrode is directly formed as the tantalum oxy-nitride film 7, which makes it possible to form a low-leakage thin-film capacitor without being affected by the trench structure.

Although the upper and lower electrodes are formed of titanium nitride films in this embodiment example, the electrodes may be formed of any other material as long as it provides the same effects. For example, the electrodes may be formed of a tantalum nitride film or tantalum film, or may be formed from tungsten, aluminum, or an alloy thereof. Although the uppermost metal film stacked on the lower electrode is formed of a tantalum nitride film, it may be formed of any other material that provides the same effects. For example, the uppermost metal film may be formed of a niobium film, a zirconia film, or a hafnium film.

### Fourth Embodiment Example

A fourth embodiment example relates to semiconductor device in which a capacity element mounted on wiring comprises an upper electrode, a capacitive insulation film, and a lower electrode stacked in this order from the top. The semiconductor device is characterized in that the lower electrode in the capacity element is buried in a groove formed by opening an insulation film formed on the wiring underneath the capacitive element so as to reach the lower wiring, whereby the lower electrode and the lower wiring are in direct contact with each other.

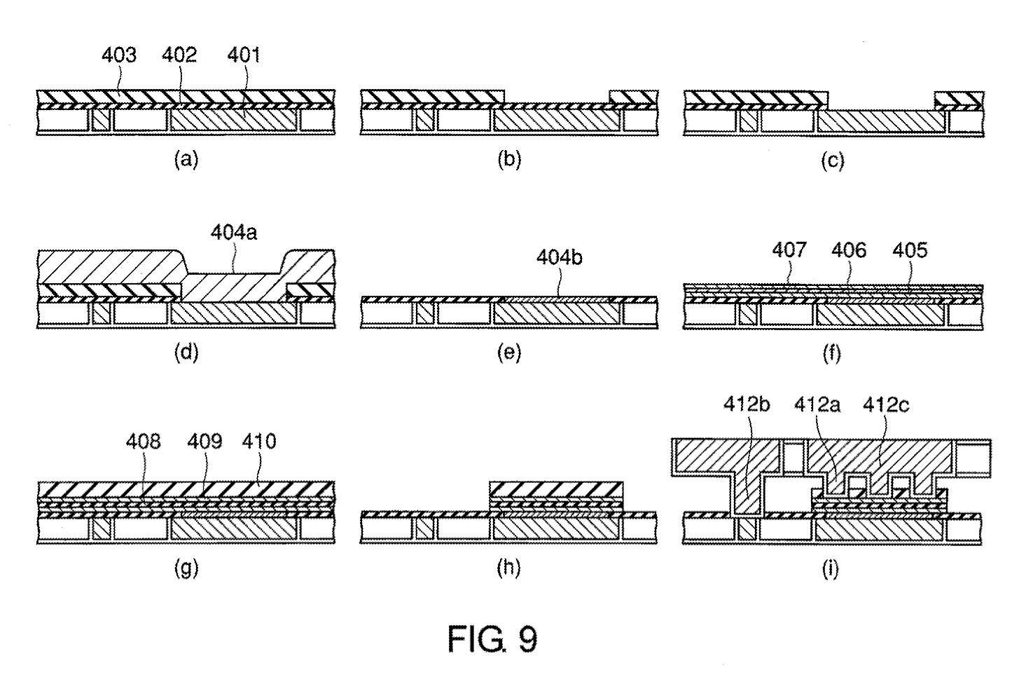

FIG. 9 shows cross-sectional views of respective steps for implementing this third embodiment example.

First, as shown in FIG. 9 (a), there are formed on lower wiring 401 primarily composed of Cu, a 120-nm thick SiN or SiCN film as a wiring cap insulation film 402 for preventing oxidation of the wiring and diffusion of the materials forming the wiring, and a 200-nm thick SiO₂ or SiOCH film as a hard mask 403. After performing photolithography and etching processes, an opening pattern is formed in the hard mask as shown in FIG. 9 (b). It is important to stop the etching on the wiring cap film 402 by utilizing the selectivity of the dry etching. After formation of the opening pattern in the hard mask, the photoresist is removed by ashing. Since the surface of the underneath wiring layer is not exposed during this ashing process, oxidation of the wiring by oxygen plasma can be prevented. The wiring cap film is etched using the hard mask with the opening pattern to form an opening pattern reaching the surface of the underneath wiring layer, as shown in FIG. 9 (c).

Subsequently, as shown in FIG. 9 (d), a 600-nm thick TaN film is formed by a sputtering method as a buried plug lower electrode 404a so that the opening described above is completely filled with the TaN. After that, the TaN except its part in the opening is removed by a CMP method, whereby a buried lower electrode 404b is formed as shown in FIG. 9 (e). The material for forming the buried electrode is not limited TaN in this example, but any other material such as Ta, Ti, W, Al, Cu, Si, an alloy or a nitride thereof may be used as long as it has a metallic or semiconducting conductivity. There will be no problem even if the hard mask is completely removed and the wiring cap film is exposed. The total thickness of the residual hard mask layer and the wiring cap layer corresponds to the thickness of the lower electrode. FIG. 9 (e) shows a case in which the structure has been polished till the wiring cap film is exposed.

By the method as described above, the buried lower electrode can be formed to be in direct contact with the underneath lower wiring layer. When Cu, which is a soft material, is used as the wiring material, dishing is prone to occur during the CMP process, and in the case of a large-area pattern, the Cu wiring will assume a shape depressed in a central part thereof. Therefore, it is difficult to form a Cu wiring with a large-area pattern. In contrast, when using TaN which is a hard material, such dishing is difficult to occur, and thus a flat surface shape can be obtained even when the pattern is of a relatively large area.

Subsequently, as shown in FIG. 9 (f), a 100-nm thick TiN film is formed by a reactive sputtering method as a principal lower electrode layer 405 constituting the gist of this invention, which is made of a polycrystalline material and shows metallic conductivity. Further, laminated films comprising a TaN film and a Ta film are formed on the lower electrode as thin metal films 406 and 407 to thicknesses of 5 nm and 10 nm or less, respectively, by the reactive sputtering method. The principal lower electrode 405 may be formed of any material as long as it has a polycrystalline structure and metallic or semiconducting conductivity. The thin metal films 406 and 407 may be formed by a single layer of the tantalum film 406, and may be made of any material an oxide of which shows a high dielectric constant and metallic or semiconducting conductivity, and exhibits selectivity of plasma oxidation. Subsequently, the thin metal films are plasma oxidized to form a tantalum oxy-nitride film 408. A TiN film is formed thereon as an upper electrode 409 by a reactive sputtering method. A SiN or SiCN film like the insulation film formed on the wiring is formed on the upper electrode as a capacitive cap insulation film 410, and the formation of the capacitive layered film is completed as shown in FIG. 9 (g).

Subsequently, as shown in FIG. 9 (h), the capacitive cap film 410, the upper electrode 409, the tantalum oxy-nitride film 408, and the lower electrode films 405 and 406 are patterned into such a shape to contain the lower electrode therein. The capacity patterning may be performed by etching the capacitive cap film 410 using a photoresist as a mask, and after ashing, etching the remaining multilayered films using the capacitive cap film 410 as a mask. After the dry etching, an insulation film is deposited, and then an upper electrode contact 412a, an upper via 412b, and upper wiring 412c are formed so as to establish contact with the thin-film capacitor (FIG. 9 (i)).

### Fifth Embodiment Example

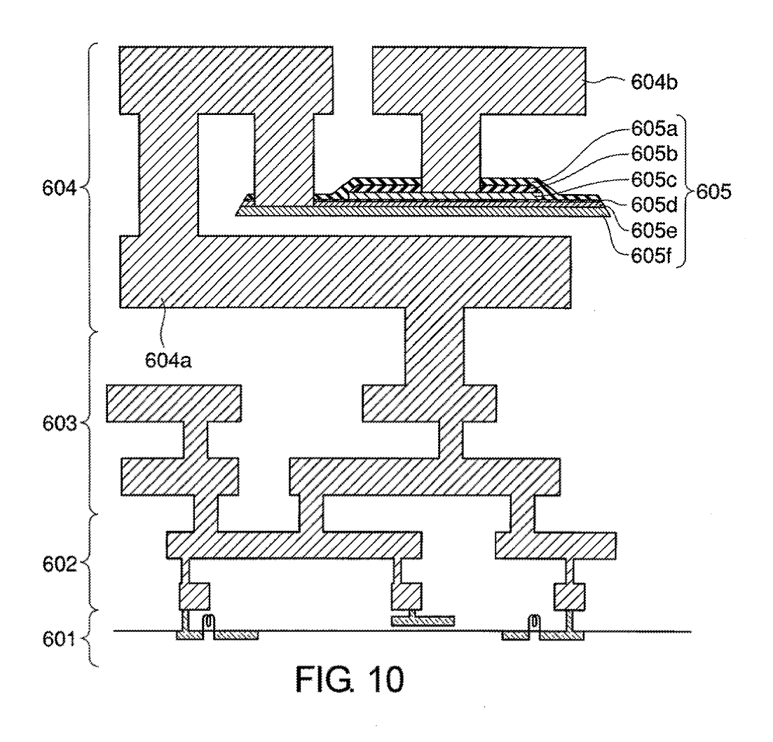

FIG. 10 shows a structural example in which a capacity element is mounted on a high-performance and high-speed processing semiconductor device for the purpose of decoupling. Some high-performance and high-speed processing semiconductor devices have a multilayer wiring structure with ten or more layers stacked. Such a multilayer wiring structure is composed of a lowermost wiring layer region 602, an intermediate wiring layer region 603, and an upper wiring layer region 604. The lowermost wiring layer region 602 has a narrow pitch and a short average wiring distance per line, and is formed by a first layer located directly on a transistor layer 601 or a plurality of layers comprising the first layer. The intermediate wiring layer region 603 has a wider pitch and a longer average wiring distance per line than the lowermost wiring layer region 602 and is formed by a single layer located higher than the lowermost wiring layer region 602 or a plurality of layers including this layer. The upper wiring layer region 604 has a wider pitch and longer average wiring distance per line than the intermediate wiring layer region 603, and is formed by a single layer located higher than the intermediate wiring layer region 603 or a plurality of layers including this layer.

Further, a pad is provided on the uppermost wiring layer to be used for connection with an external circuit. In general, the lowermost wiring layer region comprising a single layer or a plurality of layers is often used for connecting between local transistors, and hence is called “local wiring”. The intermediate wiring layer region is often used for connecting between circuit blocks comprising certain functions, and hence is called “semiglobal wiring”. The uppermost wiring layer region is often used for power supply or clock distribution, and hence is called “global wiring”. The local wiring layer region 602, comprising a narrow inter-wire pitch as described above, assumes a high inter-wire capacity, which is a factor to retard signal propagation. Therefore, a porous film, an organic film, or a film of a material comprising a low dielectric constant is used as an insulation film for insulating between the wiring layers. The term “material comprising a low dielectric constant” as used herein means a material comprising a dielectric constant of 3.0 or lower. Since recent semiconductor devices have been more and more miniaturized, a wiring structure using a low-dielectric material is employed also for the semiglobal wiring. As for the global wiring, which is designed to have a wide wiring pitch to enable supply of high-capacity current, the effects on signal propagation given by inter-wire capacity becomes less significant. Thus, a hard material such as silicon oxide is used for the global wiring for the purpose of ensuring strength and high reliability for the wiring structure. A copper-based metal with low resistance is used as a wiring material forming the multilayer structure in order to prevent retardation of signal propagation. An aluminum-based metal is used for the pad to be connected to an external circuit, and this can be used as an additional wiring layer.

When this approach is applied, there is one aluminum-based wiring layer on the copper-based wiring region of the multilayer structure. A capacity element for decoupling is inserted between a ground line and a power supply voltage line in power supply wiring. For example, like a capacity element 605 shown in FIG. 10, the capacity element is inserted in the global wiring layer region. The capacity element 605 shown here includes, for example, a hard mask 605a for formation of a lower electrode pattern, a hard mask 605b for formation of an upper electrode pattern, an upper electrode 605c, a plasma oxide film 605d, a thin metal film 605e, and a lower electrode 605f. The capacity element structure is not limited to this one, but any other structure can be employed as long as an oxide on the lower electrode exhibits a high dielectric constant.

When the element indicated by 604a in FIG. 10 is wiring for supplying power supply voltage, the element indicated by 604b is ground wiring, whereas when the element 604a is ground wiring, the element 604b is wiring for supplying power supply voltage. Although, in this example, each of the local, semiglobal, and global wiring regions comprises two layers, the number of layers comprised in each region is not limited two, but may be one, or three or more. Further, the semiglobal wiring region, which itself comprises a plurality of layers, may be formed by a wiring layer structure comprising four or more layers as a whole.

### Sixth Embodiment Example

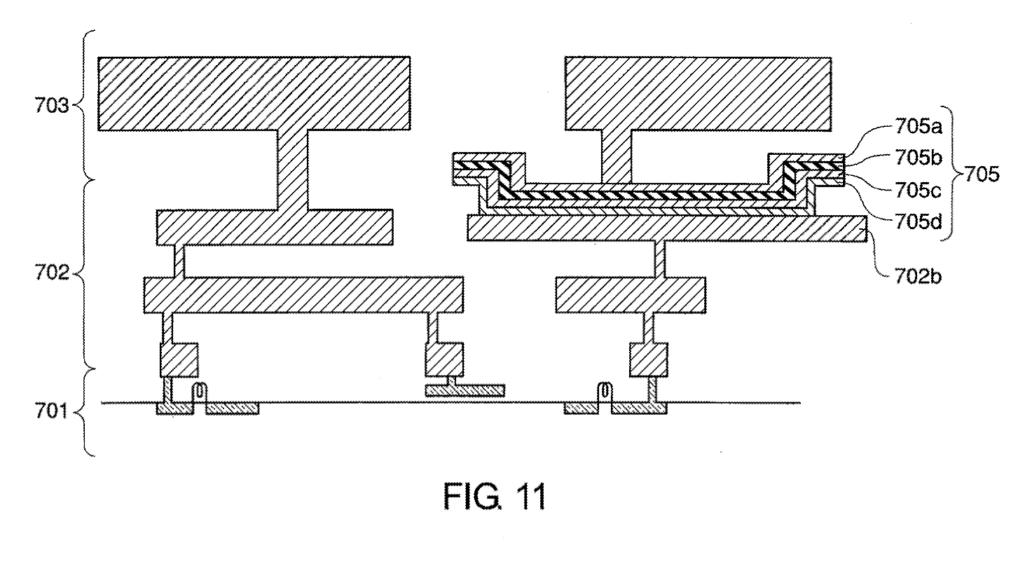

FIG. 11 shows an example in which a decoupling capacity is incorporated in a semiconductor device designed to realize reduction of cost and of power consumption. It is essential to reduce the number of wiring layers in order to realize cost reduction. Therefore, this example employs a two-stage wiring layer structure instead of the three-stage wiring layer structure as shown in the fifth embodiment example above. The two-stage wiring layer structure comprises a local wiring layer region 702 comprising a single wiring layer or a plurality of wiring layers disposed directly on a transistor formation region 701, and a global wiring layer region 703 formed on top of the local wiring layer region. Since the semiconductor device operates with low power consumption, the global wiring layer is allowed to have a relatively narrow wiring pitch, and can be formed by a single layer. Accordingly, a decoupling capacity 705 is inserted between the single global wiring layer 703 and the wiring layer disposed in the uppermost layer of the local wiring layer region 702 comprising a plurality of layers. The decoupling capacity 705 is composed of an upper electrode 705a, a plasma oxy-nitride film 705b, a thin metal film 705c, and a lower electrode 705d made of polycrystalline material, and the lower electrode 705d is physically in contact with the local wiring 702b through an opening. The structure of the decoupling capacity inserted here is not limited to the one described above, but any other structure can be employed as long as an amorphous or microcrystalline thin film is provided on a polycrystalline lower electrode.

Although FIG. 11 shows a case in which the local wiring is composed of three layers, the local wiring may be composed of a single layer, two layers, or four or more layers. Also, although the global wiring shown here is composed of a single layer, it may be composed of two or more layers. Although this structural example is shown as a two-stage structure comprising the local wiring and the global wiring for the purpose of cost reduction, a semiglobal wiring layer region may be provided between these wiring layer regions if necessary. The capacity element may be inserted between the lowermost layer in the global wiring layer region and the uppermost layer in the semiglobal wiring layer region.

### Seventh Embodiment Example

Arrangement of a capacity element constitutes a very important factor when designing a semiconductor device for processing analog or RF signals. When processing these types of signals, the circuit functions are greatly affected not only by capacitive function of the capacity element but also by parasitic resistance and parasitic inductance of electrodes, wirings and vias. Therefore, the length of wirings connecting between elements and the number of vias must be minimized as much as possible in order to suppress these parasitic components. For this reason, the capacity element is desirably arranged in a lower layer region close to the transistor.

As for the capacity element shown in the third embodiment example, the parasitic resistance of the electrodes can be minimized since a low-resistance wiring material can be used as an effective lower electrode.

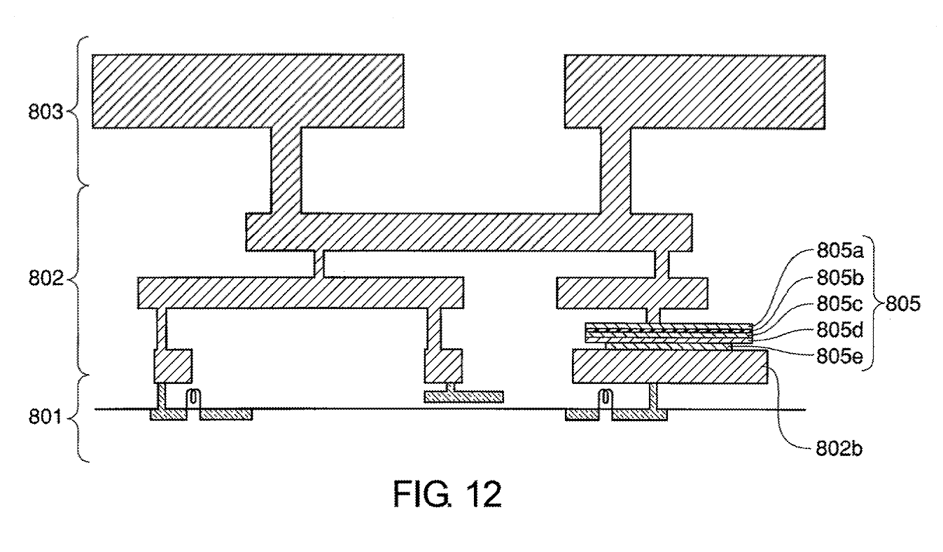

FIG. 12 is a cross-sectional structure diagram showing this seventh embodiment example. In the seventh embodiment example, a capacity element 805 is formed in the inside of a local wiring layer 802 composed of a plurality of layers formed in a region directly on a transistor formation layer 801 for enabling the capacity element to sufficiently exhibit its circuit functions. This decoupling capacity 805 is composed of an upper electrode 805a, a plasma oxy-nitride film 805b, a thin metal film 805c, a lower electrode 805d, and a conductive plug 805e formed in an insulation film formed on a lower wiring layer. The lower electrode 805d is physically in contact with the local wiring 802b through the conductive plug. The structure of the decoupling capacity to be inserted is not limited to this one shown here, but any other structure can be employed as long as an oxide exhibiting a high dielectric constant is disposed on a polycrystalline lower electrode.

As described above, the lower electrode 805d is physically in contact with the lower low-wiring layer through the conductive plug 805e buried in the insulation film formed on the lower low-resistance wiring layer. Therefore, the effective resistance of the electrode can be made extremely low, and hence the thickness of the electrode film can be minimized as possible. It is actually made possible to reduce the total thickness of the electrode film and the film 805e which is inserted on the lower electrode 805d for the purpose of planarizing the electrode surface up to about 10 to 50 nm. The reduction of the thickness of the capacity element is highly advantageous when the capacity element is inserted in the local wiring layer in which the distance between different wiring layers is as small as 100 to 200 nm.

Although this structure example shown here includes the local wiring layer region 802 composed of three layers and the global wiring layer region 803 composed of a single layer, the wiring layer structure is not limited to this, and the local wiring layer may be composed of a single layer, two layers, or four or more layers.

The global wiring layer region also may have two or more layers. Further, a semiglobal wiring layer region formed by a single layer or a plurality of layers may be inserted between the local wiring layer region and the global wiring layer region. Furthermore, the arrangement of the capacity element is not limited to the inside of the local wiring layer, but the capacity element may be formed between the local wiring layer region and the semiglobal wiring layer region, or in the inside of the semiglobal wiring layer region.

### Eighth Embodiment Example

The MIM structures as described in the first to seventh embodiment examples above may employ a structure as described below. A 10- to 100-nm thick tantalum film is formed as a lower electrode, and a 3- to 30-nm thick tantalum nitride film is stacked as a thin metal film thereon. Then, the tantalum nitride film is plasma oxidized to form a tantalum oxy-nitride film. The oxidation of the tantalum nitride film may be conducted either on the entire film or only on the surface of the film. After the plasma oxidation, any one selected from a titanium nitride film, a tantalum film, and a tantalum nitride film, or a laminated film formed by combining any of these films is formed as an upper electrode film having a thickness of 100 nm to complete an MIM structure.

This application is based upon and claims the benefit of priority from Japanese Patent Application No. 2007-071273, filed Mar. 19, 2007, the disclosure of which is incorporated herein in its entirety by reference.

1. A semiconductor device comprising a capacity structure formed by sequentially stacking a lower electrode, a capacitive insulation film, and an upper electrode on wiring or contact plug, wherein the capacity structure comprising a thin-film capacitor structure comprising an oxidized thin metal film comprising insulating properties and exhibiting a high dielectric constant, at the interface between the lower electrode and the capacitive insulation film.

2. The semiconductor device as claimed in claim 1, wherein, thermal oxidation or plasma oxidation is used for the oxidation of the thin metal film of the thin-film capacitor.

3. The semiconductor device as claimed in claim 1, wherein, the oxidation of the thin metal film of the thin-film capacitor is conducted either on the entire of the thin metal film or only on the surface of the thin metal film.

4. The semiconductor device as claimed in claim 1, wherein, the thin metal film inserted at the interface between the lower electrode and the insulation film in the thin-film capacitor has a single-layer structure or a laminated structure comprising two or more layers.

5. The semiconductor device as claimed in claim 1, wherein, in the thin-film capacitor, the thickness of the lower electrode is greater than that of the thin metal film.

6. The semiconductor device as claimed in claim 1, wherein, in the thin metal film of the thin-film capacitor, the oxidized film of the metal has a dielectric constant that is equivalent to or greater than the dielectric constant of the capacitive insulation film.

7. The semiconductor device as claimed in claim 1, wherein, the lower electrode of the thin-film capacitor is greater in size than the upper electrode, and the thin-film capacitor has a hard mask film covering the upper electrode.

8. The semiconductor device as claimed in claim 1, wherein, the thin metal film of the thin-film capacitor is a tantalum film.

9. The semiconductor device as claimed in claim 1, wherein, the thin metal film of the thin-film capacitor is a nitrogen-containing tantalum film or a tantalum nitride film.

10. The semiconductor device as claimed in claim 1, wherein, the lower electrode of the thin-film capacitor is a titanium nitride film.

11. The semiconductor device as claimed in claim 1, wherein, the upper electrode of the thin-film capacitor is any one selected from a titanium nitride film, a tantalum film, and a tantalum nitride film, or a laminated film formed by combining any of these films.

12. A semiconductor device having the thin-film capacitor as claimed in claim 1, wherein the capacitive insulation film is a thin film of an oxide of any one selected from tantalum, zirconia, hafnium, aluminum, niobium, and silicon, or is a thin film primarily composed of any oxide thereof.

13. A semiconductor device having the thin-film capacitor as claimed in claim 1, wherein the capacitive insulation film is an oxide film obtained by plasma oxidizing a thin metal film of any one selected from tantalum, zirconia, hafnium, aluminum, niobium, and silicon, or a thin metal film primarily composed of any of them.

14. A semiconductor device having multilayer wiring formed therein and wherein, the thin-film capacitor as claimed in claim 1 is formed between a power supply line and a ground line in the multilayer wiring.

15. A semiconductor device having multilayer wiring formed therein and wherein, the thin-film capacitor as claimed in claim 1 is disposed between any wiring layers vertically adjacent to each other.

16. The semiconductor device as claimed in claim 15, wherein, a wiring layer primarily composed of aluminum is formed as the uppermost layer, and copper wiring comprising multiple layers is formed thereunder.

17. The semiconductor device as claimed in claim 14, wherein, comprising multilayer wiring, at least one layer of which is formed by an interlayer insulation film containing an insulating material with a dielectric constant of 3.0 or less.

18. A manufacturing method of a semiconductor device, comprising:
forming an insulation film on wiring;
forming an opening in the insulation film;
after forming a lower electrode and a thin metal film, oxidizing only the thin metal film, and forming a capacity film and an upper electrode on the oxide film; and
etching the lower electrode from the upper electrode using a photoresist pattern corresponding to the upper electrode as a mask, and forming an upper via and upper wiring on the structure thus obtained.

19. A manufacturing method of a semiconductor device, comprising:
forming an insulation film on wiring;
after forming a lower electrode and a thin metal film, oxidizing only the thin metal film, and forming a capacity film and an upper electrode on the oxide film; and
after processing the upper electrode using a photoresist pattern corresponding to the upper electrode as a mask, processing the lower electrode using a photoresist pattern corresponding to the lower electrode, and then forming an upper via and upper wiring on the structure thus obtained.

20. A manufacturing method of a semiconductor device, comprising:
forming an insulation film on wiring;
after forming a lower electrode and a thin metal film, oxidizing only the thin metal film, and forming a capacity film and an upper electrode on the oxide film;
forming a first hard mask film of an inorganic material after forming an upper electrode;
transferring a photoresist pattern corresponding to the upper electrode to the first hard mask film;
forming a second hard mask film of an inorganic material on the front face of a wafer after processing the upper electrode using the first hard mask film as a mask; and
after transferring a photoresist pattern corresponding to the lower electrode to the second hard mask film, processing the lower electrode using the second hard mask film as a mask, and then forming an upper via and upper wiring on the structure thus obtained.

21. A manufacturing method of a semiconductor device, comprising:
forming an insulation film on wiring;
forming an opening in the insulation film;
forming a conductive plug buried in the opening by forming a film of a conductive material and polishing the same;
forming a polycrystalline or microcrystalline film on the conductive plug;
forming a thin metal film on the polycrystalline or microcrystalline film, and then oxidizing the thin metal film;
forming a capacitive insulation film and an upper electrode on the metal oxide film;
etching the lower electrode from the upper electrode using a photoresist pattern corresponding to the upper electrode and forming an upper via and upper wiring on the structure thus obtained.
